(19) United States
(12) Patent Application Publication
(10) Pub. No.: US 2012/0042927 A1
(43) Pub. Date: Feb. 23, 2012

(54) PHOTOVOLTAIC DEVICE FRONT CONTACT

(76) Inventor: Chungho Lee, San Jose, CA (US)

(21) Appl. No.: 13/213,879

(22) Filed: Aug. 19, 2011

Related U.S. Application Data
(60) Provisional application No. 61/375,738, filed on Aug. 20, 2010.

(51) Int. Cl. H01L 31/042; H01L 31/0216; H01L 31/0224; H01L 29/43; H01L 21/28

(52) U.S. Cl. 136/244; 257/749; 257/751; 438/609; 136/256; 257/E21.158; 257/E29.139

(57) ABSTRACT

A photovoltaic module may contain a front contact configured to transfer electrical current from the module.

### CLAIM OF PRIORITY

This application claims priority under 35 U.S.C. §119(e) to U.S. Provisional Patent Application Ser. No. 61/375,738 filed on Aug. 20, 2010, which is hereby incorporated by reference in its entirety.

### TECHNICAL FIELD

The present invention relates to front contacts for photovoltaic devices and methods for manufacturing photovoltaic modules.

### BACKGROUND

A photovoltaic module may include a plurality of photovoltaic devices, each of which may include a front contact. The front contact may be formed adjacent to a n-type semiconductor layer and may include a barrier layer, a transparent conductive oxide layer, and a buffer layer. The transparent conductive oxide layer may be formed through a sputtering process, which can produce an amorphous layer having poor conductivity and poor transparency. In order to transform the sputtered amorphous film to a crystalline transparent conductive oxide, an annealing process may be required. Unfortunately, the annealing process may require temperatures and durations that can limit manufacturing efficiency and cause undesirable effects within the module.

### DESCRIPTION OF DRAWINGS

FIG. 1 is a perspective view of a photovoltaic module.

FIG. 2 is a cross-sectional side view of the photovoltaic module of FIG. 1 taken along section A-A.

FIG. 3 is a cross-sectional side view of a front contact for a photovoltaic module.

FIG. 4 is a cross-sectional side view of a front contact for a photovoltaic module including a control layer.

FIG. 5 is a cross-sectional side view of a front contact for a photovoltaic module including a control layer.

FIG. 6 is a cross-sectional side view of a front contact for a photovoltaic module including a control layer.

FIG. 7 is a cross-sectional side view of a front contact for a photovoltaic module including two control layers.

FIG. 8 is a cross-sectional side view of a front contact for a photovoltaic module including three control layers.

### DETAILED DESCRIPTION

Photovoltaic cells can include multiple layers created on a substrate (or superstrate). For example, a photovoltaic cell can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the cell and/or all or a portion of the layer or substrate underlying the layer. For example, a “layer” can include any amount of any material that contacts all or a portion of a surface.

A front contact for a photovoltaic module may include multiple layers. For example, the front contact may include a barrier layer, a transparent conductive oxide layer, and a buffer layer. The layers can be deposited sequentially onto a superstrate using any suitable process such as, for example, reactive sputtering. The front contact can be heat treated to improve its optoelectronic properties. The heat treating process may cause the transparent conductive oxide to change from an amorphous structure to a crystalline structure thereby improving its conductivity and transparency. As a result of this transformation, the performance of the module is improved.

The oxide layer may include cadmium stannate which transforms from an amorphous structure to a crystalline transparent conductive oxide structure at about 600-650° C. Unfortunately, this temperature is only slightly lower than the softening temperature of soda lime glass and float glass (which can have lower iron content compared to other glass). As a result, there exists a relatively small temperature window in which annealing can be accomplished without causing softening of the glass superstrate which may produce undesirable distortions in the glass that effect the performance and structural characteristics of the resulting module.

It is desirable to develop a new front contact that includes one or more so-called “control layers” which promote transformation from an amorphous structure to a crystalline structure within the transparent conductive oxide layer, thereby permitting use of lower annealing temperatures and shorter annealing durations.

In one aspect, a multilayer structure can include a barrier layer adjacent to a substrate, an oxide layer adjacent to the barrier layer, a control layer adjacent to the transparent conductive oxide layer, and a buffer layer adjacent to the control layer. The oxide layer can include cadmium stannate. The control layer can include cadmium oxide, gallium oxide, indium oxide, cadmium indium oxide, indium tin oxide, zinc oxide, tin oxide, or zinc tin oxide. The control layer can have a thickness ranging from about 2 nm to about 100 nm.

The control layer can have a thickness ranging from about 5 nm to about 50 nm. The buffer layer can include tin oxide. The barrier layer can include silicon aluminum oxide or silicon dioxide. The substrate can include glass. The substrate can include soda-lime glass. The substrate can include float glass.

In another aspect, a multilayer structure can include a barrier layer adjacent to a substrate, a first oxide layer adjacent to the barrier layer, a control layer adjacent to the first oxide layer, a second oxide layer adjacent to the control layer, and a buffer layer adjacent to the second oxide layer. At least one of the first and second oxide layers can include cadmium stannate. The control layer can include cadmium oxide, gallium oxide, indium oxide, cadmium indium oxide, indium tin oxide, zinc oxide, tin oxide, or zinc tin oxide. The control layer can have a thickness ranging from about 2 nm to about 500 nm. The control layer can have a thickness ranging from about 5 nm to about 50 nm.

In another aspect, a multilayer structure can include a barrier layer adjacent to a substrate, a control layer adjacent to the barrier layer, an oxide layer adjacent to the control layer, and a buffer layer adjacent to the oxide layer. The oxide layer can include cadmium stannate. The control layer can include cadmium oxide, gallium oxide, indium oxide, cadmium indium oxide, indium tin oxide, zinc oxide, tin oxide, or zinc tin oxide. The control layer can have a thickness ranging from about 2 nm to about 500 nm. The control layer can have a thickness ranging from about 5 nm to about 50 nm.

In another aspect, a method for manufacturing a multilayer structure can include forming a barrier layer adjacent to a substrate, forming an oxide layer adjacent to the barrier layer, and forming a control layer adjacent to the oxide layer. Forming a control layer can include forming a control layer adjacent to the barrier layer before forming the oxide layer. Forming a control layer can include forming a control layer adjacent to the oxide layer after forming the oxide layer. The method can include forming a second oxide layer adjacent to the control layer. The method can include forming a buffer layer adjacent to the second oxide layer. The method can include forming a buffer layer adjacent to the oxide layer.

The oxide layer can include cadmium stannate. The control layer can include cadmium oxide, indium oxide, cadmium indium oxide, indium tin oxide, zinc oxide, tin oxide, or zinc tin oxide. The oxide layer can be formed using a deposition rate of about 20 angstroms/second to about 150 angstroms/second. The control layer can be formed using a deposition rate of about 20 angstroms/second to about 60 angstroms/second. The method can include annealing the oxide layer at a temperature ranging from about 550° C. to about 700° C. Annealing the oxide layer can include annealing the oxide layer at a temperature ranging from about 600° C. to about 650° C. Annealing the oxide layer can include annealing the oxide layer for a duration of about 5 minutes to about 20 minutes.

In another aspect, a photovoltaic device can include a transparent conductive oxide stack adjacent to a substrate, wherein the transparent conductive oxide stack can include a barrier layer adjacent to the substrate, a transparent conductive oxide layer, one or more control layers, and a buffer layer. The photovoltaic device can include a semiconductor window layer adjacent to the transparent conductive oxide stack, a semiconductor absorber layer adjacent to the semiconductor window layer, and a back contact layer adjacent to the semiconductor absorber layer.

The one or more control layers can be between the barrier layer and the transparent conductive oxide layer. The one or more control layers can be between the transparent conductive oxide layer and the buffer layer. The transparent conductive oxide stack can include a second transparent conductive oxide layer between the one or more control layers and the buffer layer. At least one of the transparent conductive oxide layers can include cadmium stannate. The one or more control layers can include cadmium oxide, indium oxide, cadmium indium oxide, indium tin oxide, zinc oxide, tin oxide, or zinc tin oxide. The barrier layer can include silicon aluminum oxide or silicon dioxide. The buffer layer can include tin oxide. The semiconductor window layer can include cadmium sulfide. The semiconductor absorber layer can include cadmium telluride.

In another aspect, a photovoltaic module can include a substrate and a plurality of photovoltaic cells adjacent to the substrate. At least one of the photovoltaic cells can include a transparent conductive oxide stack adjacent to the substrate. The transparent conductive oxide stack can include a barrier layer adjacent to the substrate, a transparent conductive oxide layer, one or more control layers, and a buffer layer. The photovoltaic device can include a semiconductor window layer adjacent to the transparent conductive oxide stack. The photovoltaic device can include a semiconductor absorber layer adjacent to the semiconductor window layer. The photovoltaic device can include a back contact layer adjacent to the semiconductor absorber layer. The photovoltaic module can include a back cover adjacent to the back contact layer.

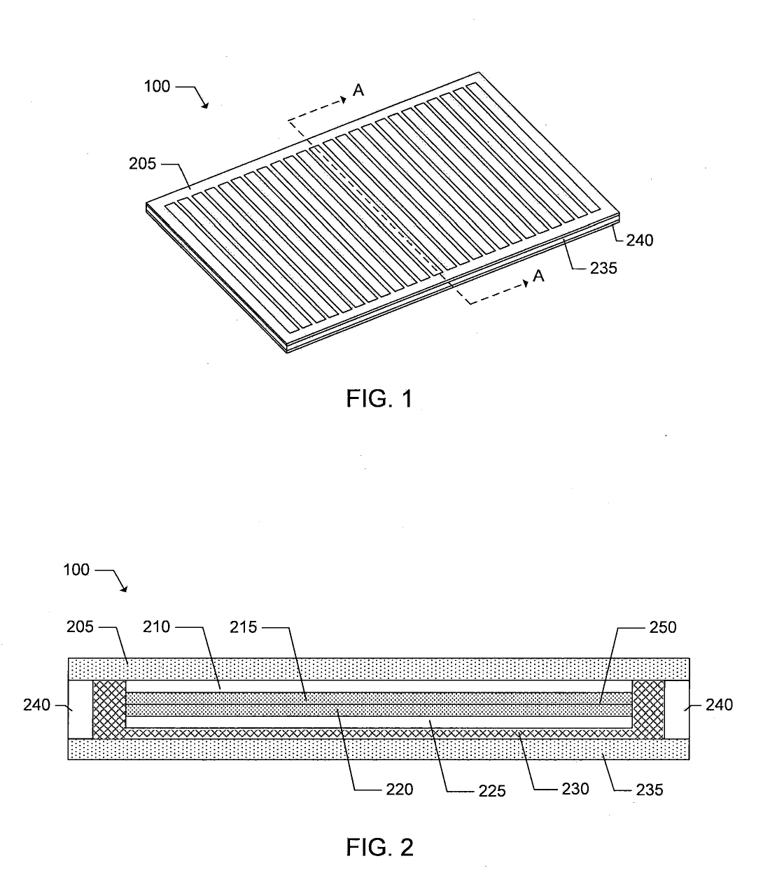

FIG. 1 shows a perspective view of a photovoltaic module 100 including a representative configuration of a representative plurality of photovoltaic devices or cells, and FIG. 2 shows a cross-sectional view of the photovoltaic module 100 taken along section A-A. The module 100 may include a superstrate layer 205. The superstrate layer 205 may include an optically transparent material such as, for example, soda-lime glass or solar float glass. For improved transmission, the glass may have low iron content.

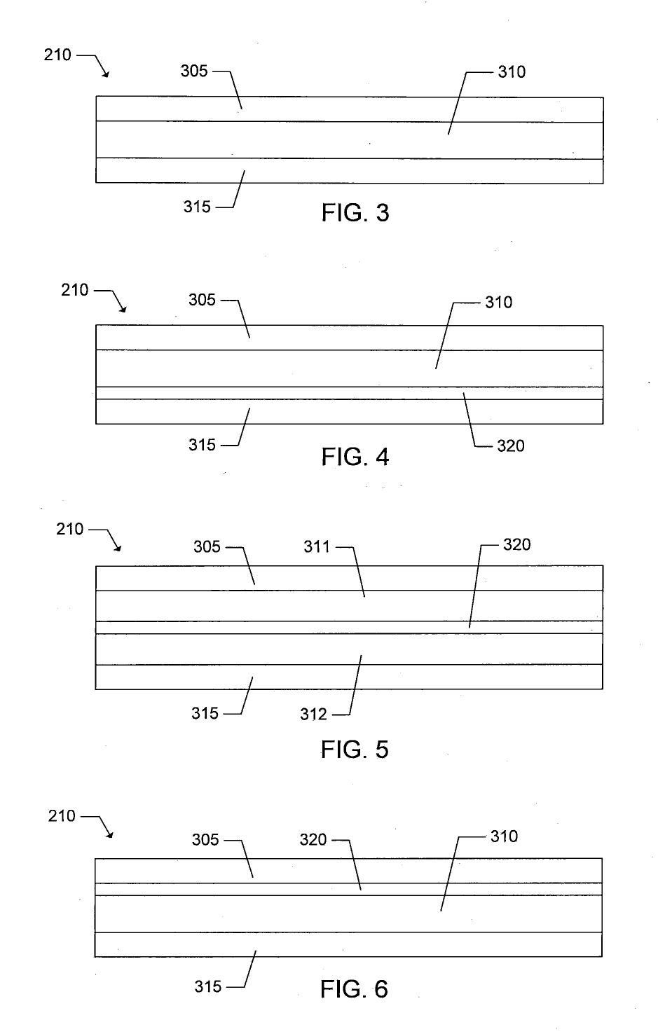

A front contact 210 may be formed adjacent to the superstrate layer 205 as shown in FIG. 2. The front contact 210 may include multiple layers. As shown in FIG. 3, the front contact 210 may include a barrier layer 305, an oxide layer 310 adjacent to a barrier layer, and a buffer layer 315 adjacent the oxide layer 310. The buffer layer 315 may improve band alignment and reduce device shunting. The barrier layer 305 may be formed adjacent to the superstrate layer 205 to lessen diffusion of sodium ions or other contaminants from the superstrate layer 205. The barrier layer 305 may include silicon dioxide, silicon aluminum oxide (SiAlOₓ), or any other suitable material. The oxide layer 310 may be formed between the barrier layer 305 and a buffer layer 315 and may be configured to transfer electrical current from the module 100.

It is desirable to select a front contact 210 having suitable optoelectronic properties. In particular, it is desirable to select a front contact 210 having high electrical conductivity and high optical transparency. To meet these requirements, the oxide layer 310 may include tin oxide, cadmium stannate, indium tin oxide, or any other suitable material. To attain the desired optoelectronic properties, the oxide layer may require thermal treatment, as a result of which, the oxide layer can have suitable transparency and conductivity, and may be considered a transparent conductive oxide (TCO) layer. For example, the oxide cadmium stannate can have an amorphous structure resulting in poor electrical conductivity and poor optical transparency. In fact, in its as-deposited state, cadmium stannate may be highly resistive and may behave similar to a dielectric material. In addition, cadmium stannate can exhibit high absorption in its as-deposited state. To improve its optoelectronic properties, cadmium stannate may be heat treated to transform its amorphous structure to a crystalline structure. Transformation to a crystalline structure may produce an oxygen deficiency within the layer, resulting in improved conductivity. The crystalline structure may also have improved optical qualities relative to the amorphous structure. In particular, it is desirable to produce a front contact having a sheet resistance less than about 20 ohms per square, less than about 15 ohms per square, less than about 10 ohms per square, or less than about 9 ohms per square. The front contact can have a resistance of less than about 9 ohms. The front contact can have an average optical absorption less than 4% between 400-850 nm.

Transformation to a crystalline structure may be accomplished by any suitable heat treatment method such as, for example, a post-sputtering annealing process. Crystallization of sputtered cadmium stannate occurs at about 600° C. Therefore, the post-sputtering annealing process may be conducted at temperatures ranging from about 550° C. to about 700° C. for durations ranging from about 5 minutes to about 20 minutes. Preferably, the post-sputtering annealing process may be conducted at temperatures ranging from about 600° C. to about 650° C. for durations ranging from about 10 minutes to about 20 minutes.

Although the post-sputtering annealing process improves the optoelectronic properties of the cadmium stannate layer, it also produces undesirable effects within the module. For example, high temperatures used in the annealing process can promote sodium diffusion from a glass superstrate layer 205. Diffusion of sodium ions can result in impurities in the module 100 which may promote leakage current, delamination of adjacent layers, micro-cracking of the TCO layer (so-called “bar graphing”), or other negative effects. The use of high temperatures during the post-sputtering annealing process may also require a barrier layer with increased thickness. But a thicker barrier layer increases module cost, so a thinner barrier layer is preferable. However, if the barrier layer 305 is too thin, it, may not sufficiently block mobile ions from migrating from the glass substrate 205 to the front contact 210.

The deposition rate used during formation of the oxide layer 310 can affect the microstructure of the oxide layer 310. In turn, the microstructure of the oxide layer 310 effects how the layer responds to heat treatment. If a lower deposition rate is used to form a oxide layer 310 including cadmium stannate, the resulting cadmium stannate layer may transform to a crystalline structure at a lower temperature during annealing. Conversely, if a higher deposition rate is used, a higher temperature may be required to transform the resulting cadmium stannate layer to a crystalline structure. Therefore, a trade-off exists where annealing temperature must be balanced with deposition rate. This trade-off is not desirable, since cost-effective, efficient manufacturing requires high deposition rates and low annealing temperatures.

FIG. 3 shows a front contact 210 having a barrier layer 305, an oxide layer 310 adjacent to the barrier layer 305, and a buffer layer 315 adjacent to the oxide layer 310. As discussed above, an annealing process occurring near 600° C. encourages transformation of amorphous cadmium stannate to a crystalline structure. Unfortunately, use of high-temperature annealing may cause interactions between adjacent layers in the module 100. In particular, there may be atomic exchanges between adjacent layers. Also, there may also be atomic exchanges between the ambient environment and the layers within the module 100.

The barrier layer 305 and the buffer layer 315 may facilitate or suppress crystallization of the cadmium stannate layer. For example, a barrier layer 305 containing silicon aluminum oxide (e.g., SiAlOₓ) or silicon dioxide (SiO₂) may suppress crystallization of the cadmium stannate. This suppression may be caused by diffusion of silicon and aluminum atoms to the cadmium stannate layer, since silicon and aluminum can suppress crystallization of sputtered oxide films. In addition, silicon aluminum oxide and silicon dioxide do not crystallize below 1000° C. Therefore, even if high-temperature annealing is employed at 600° C., a buffer layer containing silicon aluminum oxide or silicon dioxide would remain in an amorphous state. Conversely, if the buffer layer 315 contains sputtered tin oxide (e.g., SnO₂), crystallization may be achieved at a much lower temperature. In fact, some crystallites of tin oxide may be formed during the sputtering process. The crystallites may be embedded in an amorphous matrix upon formation of the buffer layer. In addition, buffer layers containing tin oxide may facilitate crystallization of the cadmium stannate layer. This is evidenced by cadmium stannate layers demonstrating enhanced optoelectronic properties when a tin oxide buffer layer is used versus no buffer layer.

To capitalize on enhanced optoelectronic properties of cadmium stannate when placed adjacent to tin oxide, a control layer 320 may be added to the front contact 210 as shown in FIGS. 4-6. The control layer 320 may effectively promote crystallization of the cadmium stannate layer, in part, by depleting oxygen and other atmospheric gases near the oxide layer 310. The control layer 320 may include cadmium oxide (CdO), indium oxide (In₂O₃), gallium oxide, cadmium indium oxide (CIO), indium tin oxide (ITO), zinc oxide (ZnO), tin oxide (SnO₂) and zinc tin oxides. The control layer 320 may have a thickness ranging from about 2 nm to about 100 nm. Preferably the control layer 320 may have a thickness ranging from about 5 nm to about 50 nm.

The control layer 320 may be formed at various locations within the front contact 210. For example, the control layer 320 may be formed between the buffer layer 315 and the oxide layer 310 as shown in FIG. 4. The control layer 320 may be formed between a first TCO layer 311 and a second TCO layer 312 as shown in FIG. 5. The control layer 320 may be formed between the barrier layer 305 and the oxide layer 310 as shown in FIG. 6.

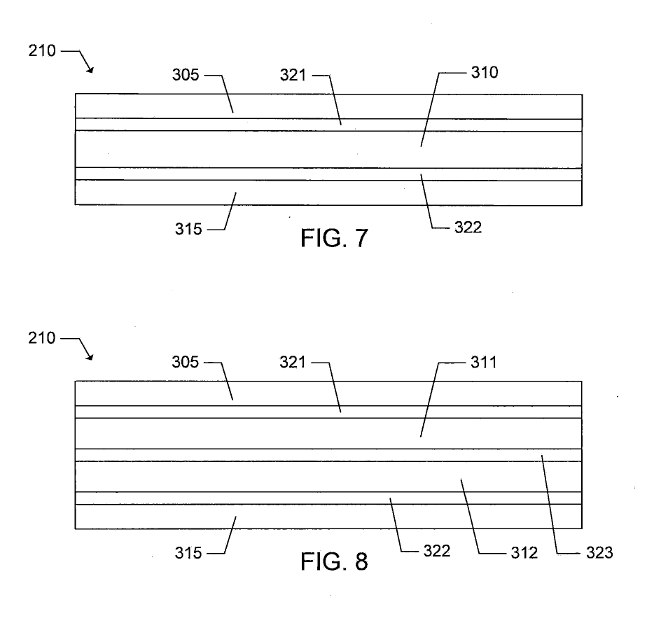

The front contact may include one or more control layers. For example, the front contact 210 may include a first control layer 321 formed between the barrier layer 305 and the TCO layer 310 and a second control layer 322 formed between the TCO layer 310 and the buffer layer 315, as shown in FIG. 7. Further, the front contact may include three control layers (321, 322, 323) as shown in FIG. 8. In particular, the front contact may include a first control layer 321 formed between the barrier layer 305 and a first TCO layer 311, a second control layer 322 formed between the second TCO layer 312 and the buffer layer 315, and a third control layer 323 formed between the first TCO layer 311 and the second TCO layer 312.

The post-deposition annealing process discussed above may be modified when a control layer 320 is included within the front contact 210. For instance, a modified post-sputtering annealing process may be conducted at temperatures ranging from about 500° C. to about 700° C. for durations ranging from about 5 minutes to about 20 minutes. Preferably, the modified post-sputtering annealing process may be conducted at temperatures ranging from about 550° C. to about 620° C. for durations ranging from about 10 minutes to about 20 minutes.

As discussed above, the deposition rate used during formation of the oxide layer 310 can affect the microstructure of the oxide layer 310, and the microstructure of the oxide layer 310 effects how the layer responds to heat treatment. However, since the control layer 320 promotes crystallization of the oxide layer 310, the tradeoff between deposition rate and annealing temperature may no longer exist. For instance, due to the presence of the control layer, higher deposition rates may be possible without requiring subsequent high-temperature annealing. In particular, the transparent conductive oxide layer may be formed using a deposition rate of about 20 angstroms/second to about 150 angstroms/second. Preferably, the transparent conductive oxide layer may be formed using a deposition rate of about 20 angstroms/second to about 60 angstroms/second. The deposition process may be followed by a post-deposition annealing process.

As shown in FIG. 2, the module 100 may include an n-type window layer 215 and a p-type absorber layer 220. The window layer 215 and the absorber layer 220 can include any suitable semiconductor material having any suitable thickness. For instance, the n-type window layer 215 may include a very thin layer of cadmium sulfide. The p-type absorber layer 220 may be formed adjacent to the n-type window layer 215 and may include any suitable active material, such as cadmium telluride or copper indium gallium (di)selenide. The window and absorber layers may be deposited using any suitable deposition method.

A p-n junction 250 is formed where the p-type absorber layer 220 meets the n-type window layer 215. When the photovoltaic module 100 is exposed to sunlight, photons are absorbed within a junction region. As a result, photo-generated electron-hole pairs are created. Movement of the electron-hole pairs is influenced by a built-in electric field, which produces current flow. The current flow occurs between a first terminal that is electrically connected to the front contact 210 and a second terminal that is electrically connected to a back contact 225. The back contact 225 may be formed adjacent to the p-type absorber layer 220. The back contact 225 may be a low-resistance ohmic contact that maintains good contact with the p-type absorber layer 220 during temperature cycling.

The various layers formed between the superstrate layer 205 and substrate layer 235 may be laminated with an interlayer 230. The interlayer 230 may protect the layers from moisture ingress and may provide containment of semiconductor materials if the photovoltaic module 100 is physically damaged. The interlayer 230 may include a polymer material such as, for example, ethylene-vinyl acetate (EVA), although any other suitable material may be used. To form the interlayer 230, various layers of the photovoltaic module 100 may be laminated with a sheet of EVA. Once the interlayer has been formed, a substrate layer 235 may be positioned adjacent to the interlayer 230. The substrate layer 235 may further protect the rear side of the module from moisture ingress or physical damage. The substrate layer 235 may include any suitable material such as, for example, soda-lime glass, solar float glass, plastic, carbon fiber, or fiberglass.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. Also, it should also be understood that the appended drawings are not necessarily to scale, presenting a somewhat simplified representation of various features and basic principles of the invention.

1. A multilayer structure comprising:
a barrier layer adjacent to a substrate;
a transparent conductive oxide layer comprising cadmium stannate adjacent to the barrier layer;
a control layer adjacent to the transparent conductive oxide layer; and
a buffer layer adjacent to the control layer.

2. (canceled)

3. The structure of claim 1, wherein the control layer comprises a material selected from the group consisting of cadmium oxide, gallium oxide, indium oxide, cadmium indium oxide, indium tin oxide, zinc oxide, tin oxide, and zinc tin oxide.

4. The structure of claim 1, wherein the control layer has a thickness ranging from about 2 nm to about 100 nm.

5. The structure of claim 1, wherein the control layer has a thickness ranging from about 5 nm to about 50 nm.

6. The structure of claim 1, wherein the buffer layer includes tin oxide.

7. The structure of claim 1, wherein the barrier layer comprises a material selected from the group consisting of silicon aluminum oxide and silicon dioxide.

8. The structure of claim 1, wherein the substrate comprises glass.

9. The structure of claim 8, wherein the substrate comprises a material selected from the group consisting of soda-lime glass and float glass.

10. (canceled)

11. A multilayer structure comprising:
a barrier layer adjacent to a substrate;
a first oxide layer adjacent to the barrier layer;
a control layer adjacent to the first oxide layer;
a second oxide layer adjacent to the control layer; and
a buffer layer adjacent to the second oxide layer,
wherein at least one of the first and second oxide layers comprises cadmium stannate.

12. (canceled)

13. The structure of claim 11, wherein the control layer comprises a material selected from the group consisting of cadmium oxide, gallium oxide, indium oxide, cadmium indium oxide, indium tin oxide, zinc oxide, tin oxide, and zinc tin oxide.

14. The structure of claim 11, wherein the control layer has a thickness ranging from about 2 nm to about 100 nm.

15. A multilayer structure comprising:
a barrier layer adjacent to a substrate;
a control layer adjacent to the barrier layer;
an oxide layer comprising cadmium stannate adjacent to the control layer; and
a buffer layer adjacent to the oxide layer.

16. (canceled)

17. The structure of claim 15, wherein the control layer comprises a material selected from the group consisting of cadmium oxide, gallium oxide indium oxide, cadmium indium oxide, indium tin oxide, zinc oxide, tin oxide, and zinc tin oxide.

18. The structure of claim 15, wherein the control layer has a thickness ranging from about 2 nm to about 100 nm.

19. A multilayer structure comprising:
a barrier layer adjacent to a substrate;
a first control layer adjacent to the barrier layer;
an oxide layer adjacent to the control layer;
a second control layer adjacent to the oxide layer; and
a buffer layer adjacent to second control layers
wherein the first and second control layers comprise cadmium stannate.

20. (canceled)

21. The structure of claim 19, wherein the first and second control layers comprise a material selected from the group consisting of cadmium oxide, gallium oxide indium oxide, cadmium indium oxide, indium tin oxide, zinc oxide, tin oxide, and zinc tin oxide.

22. The structure of claim 19, wherein the control layer has a thickness ranging from about 2 nm to about 100 nm.

23. A method for manufacturing a multilayer structure, the method comprising:
forming a barrier layer adjacent to a substrate;
forming an oxide layer comprising cadmium stannate over the barrier layer; and
forming a control layer adjacent to the oxide layer.

24. The method of claim 23, wherein forming the control layer comprises forming the control layer adjacent to the barrier layer before forming the oxide layer adjacent to the control layer.

25. The method of claim 23, wherein forming the control layer comprises forming the control layer adjacent to the oxide layer after forming the oxide layer adjacent to the barrier layer.

26. The method of claim 23, further comprising forming a second oxide layer adjacent to the control layer.

27. The method of claim 26, further comprising forming a buffer layer adjacent to the second oxide layer.

28. The method of claim 23, further comprising forming a buffer layer adjacent to the oxide layer.

29. (canceled)

30. The method of claim 23, wherein the control layer comprises a material selected from the group consisting of cadmium oxide, gallium oxide, indium oxide, cadmium indium oxide, indium tin oxide, zinc oxide, tin oxide, and zinc tin oxide.

31. The method of claim 23, wherein the oxide layer is formed using a deposition rate of about 20 angstroms/second to about 150 angstroms/second.

32. The method of claim 23, wherein the control layer is formed using a deposition rate of about 20 angstroms/second to about 60 angstroms/second.

33. The method of claim 23, further comprising annealing the oxide layer at a temperature ranging from about 550° C. to about 700° C.

34. The method of claim 33, wherein annealing the oxide layer comprises annealing the oxide layer for a duration of about 5 minutes to about 20 minutes.

35. A photovoltaic device comprising:
a transparent conductive oxide stack adjacent to a substrate, wherein the transparent conductive oxide stack comprises a barrier layer adjacent to the substrate, a transparent conductive oxide layer comprising cadmium stannate, a control layer, and a buffer layer;
a semiconductor window layer adjacent to the transparent conductive oxide stack;
a semiconductor absorber layer adjacent to the semiconductor window layer; and
a back contact layer adjacent to the semiconductor absorber layer.

36. The photovoltaic device of claim 35, wherein the control layer is between the barrier layer and the transparent conductive oxide layer.

37. The photovoltaic device of claim 35, wherein the control layer is between the transparent conductive oxide layer and the buffer layer.

38. The photovoltaic device of claim 35, wherein the transparent conductive oxide stack further comprises a second transparent conductive oxide layer between the control layer and the buffer layer.

39. The photovoltaic device of claim 38, wherein the second transparent conductive oxide layers comprises cadmium stannate.

40. The photovoltaic device of claim 35, wherein the control layer comprises a material selected from the group consisting of cadmium oxide, gallium oxide, indium oxide, cadmium indium oxide, indium tin oxide, zinc oxide, tin oxide, and zinc tin oxide.

41. The photovoltaic device claim 35, wherein the barrier layer comprises a material selected from the group consisting of silicon aluminum oxide and silicon dioxide.

42. The photovoltaic device of claim 35, wherein the buffer layer comprises tin oxide.

43. The photovoltaic device of claim 35, wherein the semiconductor window layer comprises cadmium sulfide.

44. The photovoltaic device of claim 35, wherein the semiconductor absorber layer comprises cadmium telluride.

45. A photovoltaic module comprising:
a substrate;
a plurality of photovoltaic cells adjacent to the substrate, at least one of the photovoltaic cells comprising
a transparent conductive oxide stack adjacent to a substrate, wherein the transparent conductive oxide stack comprises a barrier layer adjacent to the substrate, a transparent conductive oxide layer comprising cadmium stannate, a control layer, and
a buffer layer;
a semiconductor window layer adjacent to the transparent conductive oxide stack;
a semiconductor absorber layer adjacent to the semiconductor window layer; and
a back contact layer adjacent to the semiconductor absorber layer; and
a back cover adjacent to the back contact layer.

46. The module of claim 45, wherein the transparent conductive oxide stack has a sheet resistance less than 9 ohms.

47. The module of claim 45, wherein the transparent conductive oxide stack has an average optical absorption less than 4% when exposed to light having wavelengths ranging from about 400 nm to about 850 nm.
